(19) United States
(12) Patent Application Publication
(10) Pub. No.: US 2013/0340941 A1
(43) Pub. Date: Dec. 26, 2013

(54) LENS OFFSET

(71) Applicant: TEL Solar AG, Trubbach (CH)

(72) Inventor: Stephan JOST, Azmoos (CH)

(21) Appl. No.: 13/916,685

(22) Filed: Jun. 13, 2013

Related U.S. Application Data
(60) Provisional application No. 61/661,868, filed on Jun. 20, 2012.

(51) Int. Cl. H01J 37/32

(52) U.S. Cl. CPC H01J 37/32568
USPC 156/345.48; 118/723 I

(57) ABSTRACT

This disclosure relates a system and techniques for adjusting component parts of a Plasma-enhanced processing system. The electric field uniformity generated by plasma processing may be improved by adjusting the distance between a cavity of an upper electrode and an insulating plate that covers, at least a portion of, the cavity. In another embodiment, the electric field uniformity may be improved by adjusting the distance between the substrate and the upper electrode.

### CROSS REFERENCE TO RELATED APPLICATIONS

This application claims priority to provisional application 61/661,868 filed on Jun. 20, 2012. The provisional application is incorporated by reference in its entirety into this application.

TECHNICAL FIELD

This disclosure generally relates to systems and/or devices used in a plasma-processing chamber. This may include, but is not limited to, plasma-enhanced chemical vapor deposition or plasma etching. More particularly, this disclosure relates to a voltage and electrical field non-uniformity compensation method for large area and/or high frequency plasma reactors. This method is generally applicable to rectangular or square large area plasma processing equipment which for instance is used in LCD and Solar Cell production.

### BACKGROUND

Plasma may be generated in a vacuum chamber by providing electrical energy in the radio frequency range to ionize processes gases that may be enclosed in the vacuum chamber at sub-atmospheric pressures. Plasma processing may be used to etch a substrate or deposit a film on the substrate. The quality of the plasma processing may be based, at least in part, on the uniformity of the plasma. In certain instances, controlling the location and uniformity of the plasma in the vacuum chamber may be desirable for substrate processing quality and/or limiting the impact of the plasma to desired regions of the vacuum chamber that may be beneficial for substrate processing or vacuum chamber longevity.

### BRIEF DESCRIPTION OF THE FIGURES

The features within the drawings are numbered and are cross-referenced with the written description. Generally, the first numeral reflects the drawing number where the feature was first introduced, and the remaining numerals are intended to distinguish the feature from the other notated features within that drawing. However, if a feature is used across several drawings, the number used to identify the feature in the drawing where the feature first appeared will be used. Reference will now be made to the accompanying drawings, which are not necessarily drawn to scale and wherein:

FIG. 1 illustrates a cross section view of a representative plasma processing system that may include an upper and lower electrode for processing substrates. The upper electrode may include a cavity that may be covered by an insulating plate as described in one or more embodiments of the disclosure.

FIG. 2 illustrates a cross section view of a representative plasma processing system that may include an upper and lower electrode for processing substrates. The upper electrode may include a cavity that may be covered by an insulating plate that is offset from the upper electrode as described in one or more embodiments of the disclosure.

FIG. 3 illustrates a cross section view of a representative plasma processing system that may include an upper and lower electrode for processing substrates. The substrate may be offset from the lower electrode as described in one or more embodiments of the disclosure.

FIG. 4 illustrates a graph showing the shape of the cavity of the upper electrode as described in one or more embodiments of the disclosure.

### SUMMARY

Embodiments described in this disclosure may relate to the arrangement or design of plasma processing components used to etch a substrate or deposit a film on a substrate. Broadly, the plasma process chamber may include a vacuum chamber that may be held at sub-atmospheric pressure. The plasma process chamber may also include a gas distribution system to provide process gases that may be used to generate plasma. Plasma may be ignited by a radio frequency (RF) power system that may include one or more electrodes that may be used to ionize the process gases using RF power that is provided to the one or more electrodes. For example, a substrate may be placed below or adjacent to an electrode. The electrode may be placed a certain distance above or near the substrate to adjust or control the uniformity of the plasma above or around the substrate. A higher degree of plasma uniformity may result in a more uniform film deposition across the substrate.

In one embodiment, the electrode may include a sloped cavity along at least a portion of the electrode. The slope of the cavity may be optimized based, at least in part, on whether the cavity is maintained at vacuum, includes a dielectric material, or one or more gases. An insulating plate may cover at least a portion of the cavity. The geometry of the cavity may be optimized based, at least in part, on a lens distance and a substrate distance. In one instance, the lens distance may be the maximum distance that separates the electrode and the insulating plate over the cavity portion of the electrode. The substrate distance may be a distance between the insulating plate and the substrate placed below the electrode. In this embodiment, the insulating plate may be placed flush with the electrode such that the lens distance is approximate to the maximum depth of the cavity.

In another embodiment, the insulating plate may be offset from the cavity such that the lens distance is greater than the maximum depth of the cavity. In one instance, offset spacer may be placed between the insulating plate and the electrode to increase the lens distance. In this embodiment, the lens distance may also be referred to as the offset distance. Broadly, the offset distance may be less than or equal to 3 mm. In one particular embodiment, the offset distance may be approximately 0.3 mm.

The offset distance may vary on desired process conditions or process performance requirements. For example, the offset distance may be based, at least in part, on an applied frequency of the RF power system, a size of the electrode, and/or the substrate distance.

In another embodiment, the placement of the substrate may be used to optimize process conditions instead of the placement of the insulating plate. For example, the substrate distance may be optimized by placing spacers below the substrate instead of placing spacers between the electrode and the insulating plate.

Example embodiments of the disclosure will now be described with reference to the accompanying figures.

### DETAILED DESCRIPTION

Embodiments of the invention are described more fully hereinafter with reference to the accompanying drawings, in which embodiments of the disclosure are shown. This disclosure may, however, be embodied in many different forms and should not be construed as limited to the embodiments set forth herein; rather, these embodiments are provided so that this disclosure will be thorough and complete, and will fully convey the scope of the disclosure to those skilled in the art.

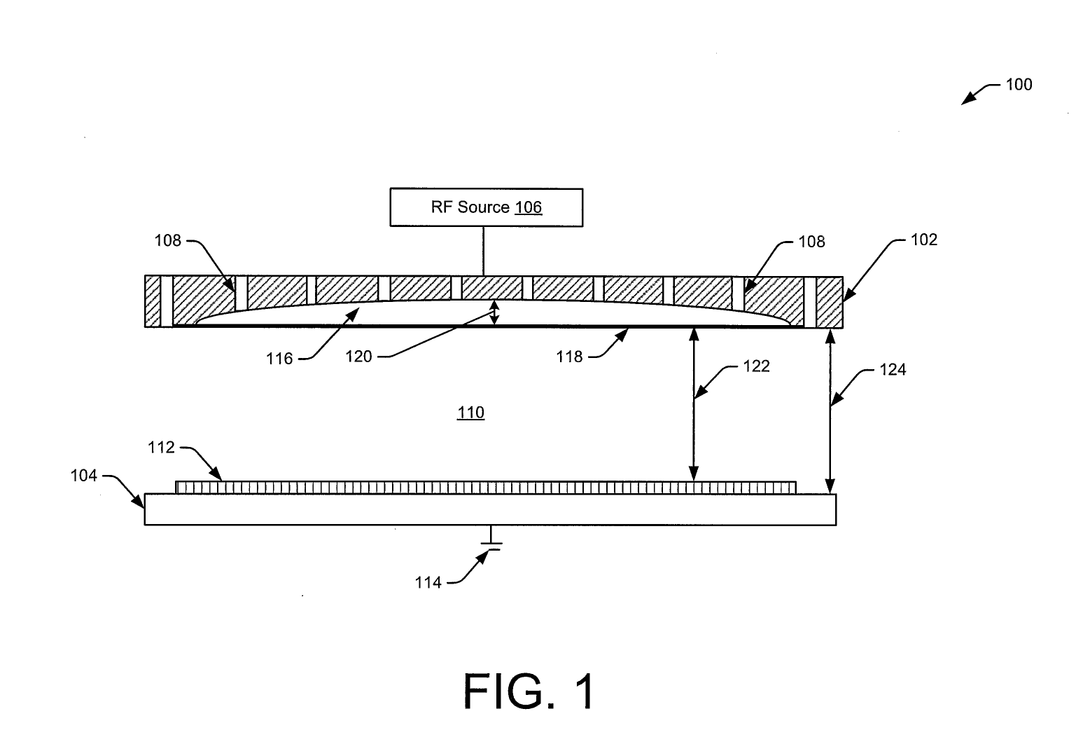

FIG. 1 illustrates a cross section view of a representative plasma processing system 100 that may be used for processing substrates using plasma. The system 100 may include an upper electrode 102, a lower electrode 104, and a radio frequency source 106 that provides power to the upper electrode 102. A gas distribution system (not shown) may also provide process gases to the upper electrode 102, which are distributed by a plurality of gas portals 108. In this embodiment, the upper electrode 102 and the lower electrode 104 may be separated by a plasma-processing region 110. A substrate 112 may be placed on the lower electrode 104 adjacent to the plasma-processing region 110. In this instance, the lower electrode 104 may be coupled to an electrical ground 114.

In one embodiment, the upper electrode 102 may include a cavity 116 that may be at least partially covered by an insulating plate 118. The cavity 116 may be used to obtain a more uniform electrical field that may be generated when power is applied to the upper electrode 102. Broadly, the cavity 116 may be a concave cavity within the upper electrode, as shown in FIG. 1. The cavity 116 may be sloped from an exterior surface of the upper electrode 102 to a maximum distance or lens distance 120 that may be near the center of the upper electrode 102. The slope of the cavity 116 depends mainly on the electrode size, the generator frequency and the plasma gap. As an example for a 1.1×13 m electrode at 40 Mhz and a plasma gap of <10 mm the cavity may be approximately 1.2 mm deep.

The contents of the cavity 116 may vary depending on the desired process conditions to etch or deposit on the substrate 112. The contents of the cavity 116 may impact the uniformity of the electric field generated during plasma processing. In one embodiment, the cavity 116 may be held under sub-atmospheric pressure conditions which may or may not include process gases. In another embodiment, the cavity 116 may also include a dielectric material that may be flush with the insulating plate 118 and/or the cavity 116 of the upper electrode 102.

The insulating plate 118 may cover the cavity 116 and may be separated from the substrate 112 by a processing distance 122. This distance may be measured from the exterior surface of the insulating plate 118 that may be facing the substrate 112 to a surface of the substrate 112 that may be facing the insulating plate 118. In this embodiment, the electrode separation distance 124 may be measured between the surfaces of the upper electrode 102 and the lower electrode 104 that may be facing each other. In the FIG. 1 embodiment, the electrode separation distance 124 may be the thickness of the substrate 112 plus the processing distance 122. In one embodiment, the thickness of the substrate may be less than 5 mm. In one particular embodiment, the thickness of the substrate 112 may be approximately 3 mm.

The system 100 may also be varied further to optimize or control the uniformity of the electrical field in the region of the upper electrode and/or plasma-processing region 110. The optimization may include, but is not limited to, varying the lens distance and/or the processing distance 122.

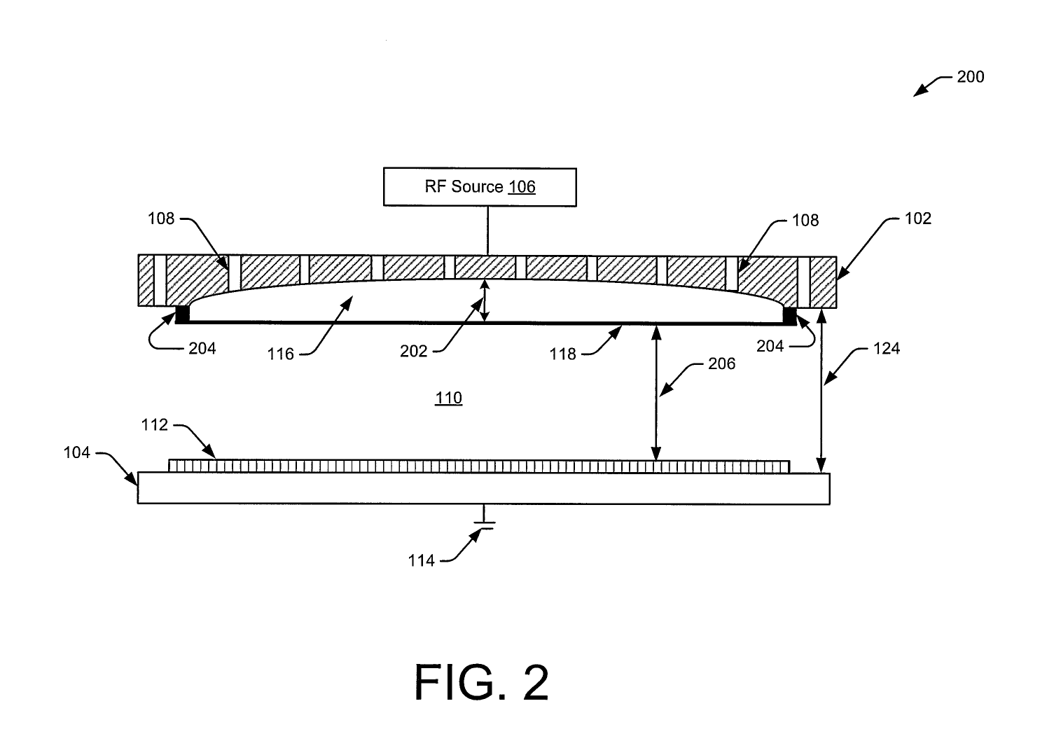

FIG. 2 illustrates a cross section view a representative plasma processing system 200 that may increase the lens distance 202 by adding spacers 204 between the insulating plate 118 and the upper electrode 102. In contrast to FIG. 1, the lens distance 202 is larger and the plasma-processing distance 206 is smaller. For example, the lens distance 120 in FIG. 1 may be approximately 0.5 mm. In contrast to FIG. 2, the spacers 204 between the upper electrode 102 and the insulating plate 118 may increase the lens distance to approximately 2.5 mm. In this embodiment, the electrode separation distance 124, as shown in FIG. 2, may be similar to the electrode separation distance 124 shown in FIG. 1.

In one embodiment, the spacer 204 may be a dielectric material that may be coupled to the upper electrode 102. The spacer 204 may be continuous along the perimeter of the cavity 116. In this way, the spacer 204 may form a leak tight seal between the upper electrode 102 and the insulating plate 118. For example, the leak tight seal may be applicable when sub-atmospheric pressure is desired between the upper electrode 102 and the insulating plate 118.

In another embodiment, the spacer 204 may be integrated into dielectric material that may fill, at least a portion of, the cavity 116. In this way, the dielectric material may fill at least a portion of the cavity 116 while offsetting the insulating plate 118 from the upper electrode 102.

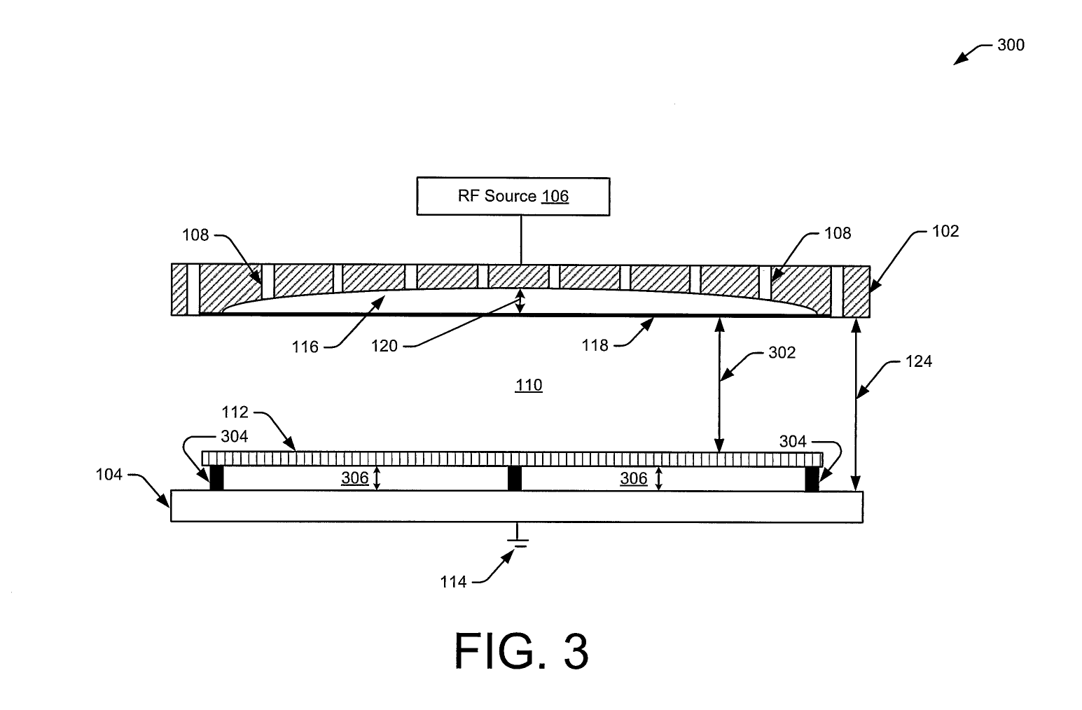

FIG. 3 illustrates a cross section view of a representative plasma processing system 300. In this embodiment, the processing distance 302 between the insulating plate 118 and the substrate 112 may be adjusted by placing substrate spacers 304 below the substrate 112. The substrate spacer distance 306 being at most approximately 3 mm. As shown in FIG. 3, the insulating plate 118 may be placed flush with the upper electrode 102. In this embodiment, the insulating plate may cover the cavity 116 to enable a sub-atmospheric pressure within the cavity 116.

In one embodiment, the substrate spacers 304 may include, but are not limited to, three separate ridges that are placed on a surface of the lower electrode 104. In this instance, there may be a gap between the substrate 112 and the lower electrode 104. However, in other embodiments, the substrate spacers 304 may be arranged to minimize the size of the gap or eliminate the gap to prevent process gases or plasma from reaching the backside of the substrate 112.

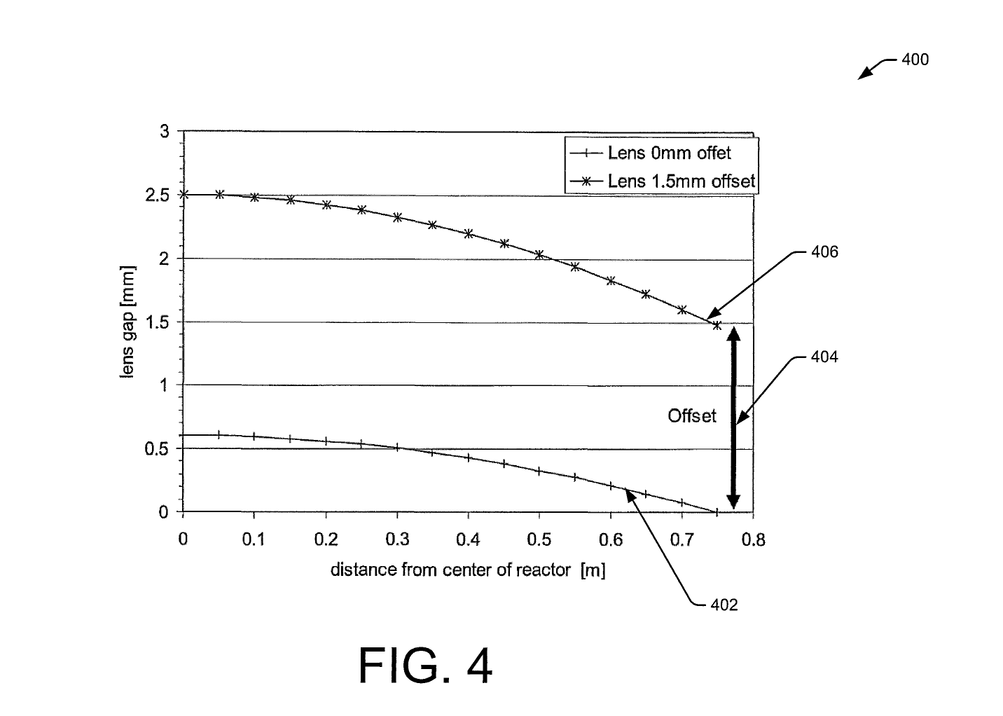

FIG. 4 illustrates a graph 400 showing one embodiment of the shape of the cavity 116 of the upper electrode 102 as shown FIG. 1. For example, the x-axis represents the distance from the center of the reactor or cavity 116 and the y-axis represents the distance from a surface of the cavity 116 to the insulating plate 118. In this instance, the center of the reactor may have the largest distance between the cavity 116 surface and the insulating plate 118.

In this instance, the FIG. 1 embodiment may be represented in the 0 mm offset line 402 which reflects a gap distance of 0.6 mm at the center of the cavity 116 and a minimum gap distance of approximately zero at the edge of the cavity at 0.75 m. In contrast, the offset 404 increase, as illustrated in the system 200 in FIG. 2, may be represented by the 1.5 mm offset line 406. The center gap distance may be approximately 2.5 mm and the edge gap distance may be approximately 1.5 mm.

In other embodiments, the offset line 406 may vary between 0.6 mm and 3 mm depending on the impact of the electrical field uniformity desired for the plasma process using system 200.

What is claimed:

1. A plasma reactor, comprising:
a first metal electrode comprising a concave portion that is covered by an insulating plate that is offset from the concave portion of the first metal electrode by an offset distance;
a second metal electrode disposed across from the first metal electrode with the insulating plate facing the second metal electrode; and
a Radio Frequency (RF) source configured to provide power to ionize molecules between the insulating plate and the second metal electrode.

2. The plasma reactor of claim 1, wherein the concave portion comprises a dielectric material between the first metal electrode and the insulating plate.

3. The plasma reactor of claim 2, wherein the dielectric material is in flush contact with the concave portion and the insulating plate.

4. The plasma reactor of claim 1, further comprising a vacuum gap between the concave portion and the insulating plate.

5. The plasma reactor of claim 4, wherein the vacuum gap can maintain a pressure less than atmospheric pressure.

6. The plasma reactor of claim 1, wherein the insulating plate is offset from the first metal electrode by an offset distance that is based, at least in part, on one or more of the following: an applied frequency of the RF source, a size of the first metal electrode, or a distance between the insulating plate and the second metal electrode.

7. The plasma reactor of claim 1, wherein the offset distance comprises a distance less than or equal to 3 mm.

8. A device, comprising:
a metal electrode comprising a concave portion that extends from a perimeter of the metal electrode to a high point near or along a center line of the metal electrode; and
a non-conductive plate that is substantially planar and covers the concave portion, the non-conductive plate being offset from an outer perimeter of the concave portion by an offset distance.

9. The device of claim 8, wherein the concave portion comprises a dielectric material between the metal electrode and the non-conductive plate, and the offset distance comprises a range of about 3 mm to 30 mm.

10. The device of claim 8, wherein the concave portion and the non-conductive plate are coupled together to comprise a cavity that can maintain a pressure less than atmospheric pressure.

11. The device of claim 8, wherein the concave portion comprises a concavity that is based, at least in part, on a magnitude of the offset distance.

12. The device of claim 8, wherein the offset distance comprises a range of about 0.3 mm to about 2 mm.

13. The device of claim 8, wherein the metal electrode is a first metal electrode and further comprising a second metal electrode disposed subjacent to the non-conductive plate of the first metal electrode.

14. The device of claim 8, wherein the offset distance is based, at least in part, on a frequency of power applied to the metal electrode and a size of the metal electrode.

15. A system, comprising:
a first conductive electrode comprising:
a concave portion with a concavity that defines the slope profile of the concave portion; and
an insulating plate that covers the concave portion and is on the same plane as an open end of the concave portion;
a second conductive electrode disposed across from the first conductive electrode; and
a substrate spacer component protruding from the second conductive electrode to support a substrate at an offset distance from the second conductive electrode, the offset distance having magnitude that is based, at least in part, on the concavity of the concave portion.

16. The system of claim 15, wherein the concave portion comprises a dielectric material between the first conductive electrode and the insulating plate.

17. The system of claim 15, wherein the concave portion and the insulating plate are coupled together to comprise a cavity that can maintain a pressure less than atmospheric pressure.

18. The system of claim 15, wherein the concavity monotonically decreases along at least a portion of the first conductive electrode between a central region of the concave portion to a peripheral region of the concave portion.

19. The system of claim 15, wherein the insulating plate is offset from the first conductive electrode by an offset distance that is based, at least in part, on a frequency of power applied to the first conductive electrode or the second conductive electrode, a size of the first conductive electrode, and a distance between the insulating plate and the second conductive electrode.

20. The system of claim 15, further comprising a Radio Frequency power source that provides alternating power to ionize molecules between the first conductive electrode and the second conductive electrode.
